(19) United States
(12) Patent Application Publication
(10) Pub. No.: US 2014/0042552 A1
(43) Pub. Date: Feb. 13, 2014

(54) SEMICONDUCTOR DEVICE AND METHOD OF MANUFACTURING SAME

(71) Applicant: Renesas Electronics Corporation, Kawasaki-shi (JP)

(72) Inventors: Hiromasa Yoshimori, Kanagawa (JP); Toshiaki Iwamatsu, Kanagawa (JP)

(73) Assignee: Renesas Electronics Corporation, Kawasaki-shi (JP)

(21) Appl. No.: 13/958,592

(22) Filed: Aug. 4, 2013

(30) Foreign Application Priority Data
Aug. 8, 2012 (JP) 2012-175804

(51) Int. Cl. H01L 27/06; H01L 29/66

(52) U.S. Cl. CPC H01L 27/0617; H01L 29/66492
USPC 257/392; 438/275

(57) ABSTRACT

Provided is a semiconductor device having an insulating gate field effect transistor equipped with a metal oxide film in a portion, on the side of a source region, between a gate insulating film and a gate electrode. The metal oxide film is provided above a p⁺ type semiconductor region for punch-through stopper so as to cover the entire region thereof. Such a metal oxide film contributes to a decrease in the impurity concentration of the p⁺ type semiconductor region, making it possible to reduce variations in the threshold voltage of the transistor. On the side of a drain region, the gate insulating film is formed as a single film without stacking the metal oxide film thereon. As a result, the resulting transistor can escape deterioration in reliability which will otherwise occur due to hot carriers on the side of the end of the drain region.

### CROSS-REFERENCE TO RELATED APPLICATIONS

The disclosure of Japanese Patent Application No. 2012-175804 filed on Aug. 8, 2012 including the specification, drawings and abstract is incorporated herein by reference in its entirety.

### BACKGROUND

The present invention relates to a semiconductor device and a method of manufacturing the same. They can be utilized preferably for, for example, a semiconductor device having an insulating gate field effect transistor and a method of manufacturing the semiconductor device.

The operating voltage of an insulating gate field effect transistor for the input/output circuit of LSI cannot be decreased because it is determined depending on the relationship with an external circuit and therefore does not comply with scaling rules. Under a predetermined operating voltage, therefore, it is required to suppress occurrence of punch-through between source and drain regions and relax the electric field at the end of the drain region to suppress generation of impact ions.

As one example of a structure capable of suppressing generation of impact ions, an LDD (lightly doped drain) structure or extension structure is known. Such a structure has, on the gate electrode side of the source-drain region of an insulating gate field effect transistor, a semiconductor region having an impurity concentration lower than that of the source-drain region. This makes it possible to relax the electric field in a channel direction in the vicinity of the drain region, thereby suppressing generation of impact ions.

In addition, as one example of a structure capable of suppressing generation of punch-through, a punch-through stopper structure called pocket or halo is known. This structure has, in the vicinity on the side of a gate electrode in a semiconductor region for LDD or extension on the side of a source region, a semiconductor region having a conductivity type opposite to that of the source region. This makes it possible to suppress extension of a depletion layer from the side of a drain region toward the side of the source region, thereby suppressing generation of punch-through between source-drain regions.

It is to be noted that, for example, Patent Documents 1 to 3 disclose a technology of using a hafnium-based high-dielectric constant film for some of gate insulating films of an insulating gate field effect transistor.

### BRIEF DESCRIPTION OF THE DRAWINGS

[Patent Document 1] Japanese Patent Laid-Open No. 2006-210636
[Patent Document 2] Japanese patent Laid-Open No. 2008-27955
[Patent Document 3] Japanese Patent Laid-Open No. 2004-207517

### SUMMARY

However, when with miniaturization of insulating gate field effect transistors, their gate length becomes shorter, the impurity concentration of the semiconductor region for punch-through stopper should be increased in order to keep short-channel characteristics. An increase in the impurity concentration of the semiconductor region for punch-through stopper however leads to a problem, that is, variations in threshold voltage.

Another problem and novel features of the invention will be apparent from the description herein and accompanying drawings.

A semiconductor device according to one embodiment has a first insulating gate field effect transistor equipped with a metal oxide film in a portion, on the side of a source region, between a gate insulating film and a gate electrode on a semiconductor substrate.

A method of manufacturing a semiconductor device according to one embodiment has a step of, in forming a first insulating gate field effect transistor over a semiconductor substrate, forming a metal oxide film in a portion, on the side of a source region, between a gate insulating film and a gate electrode.

The embodiments of the invention make it possible to reduce variations in threshold voltage of an insulating gate field effect transistor which includes a semiconductor device.

### BRIEF DESCRIPTION OF THE DRAWINGS

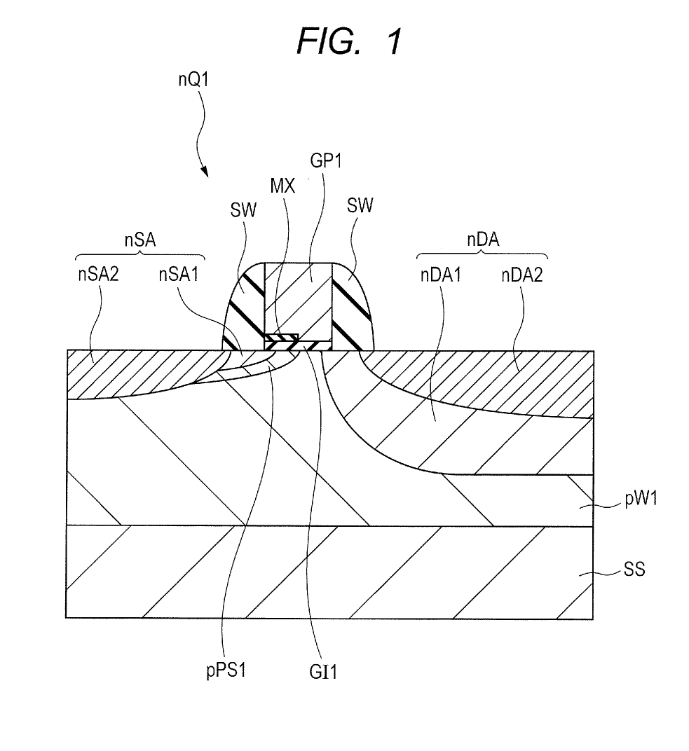

FIG. 1 is a fragmentary cross-sectional view of a semiconductor device according to First Embodiment;

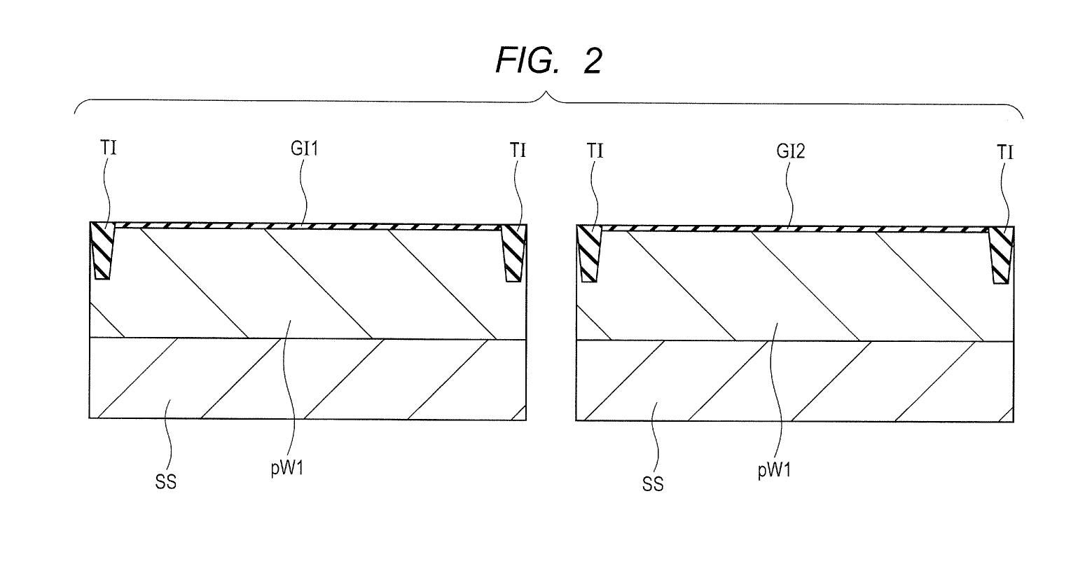

FIG. 2 is a fragmentary cross-sectional view of a semiconductor substrate during a manufacturing step of the semiconductor device of FIG. 1;

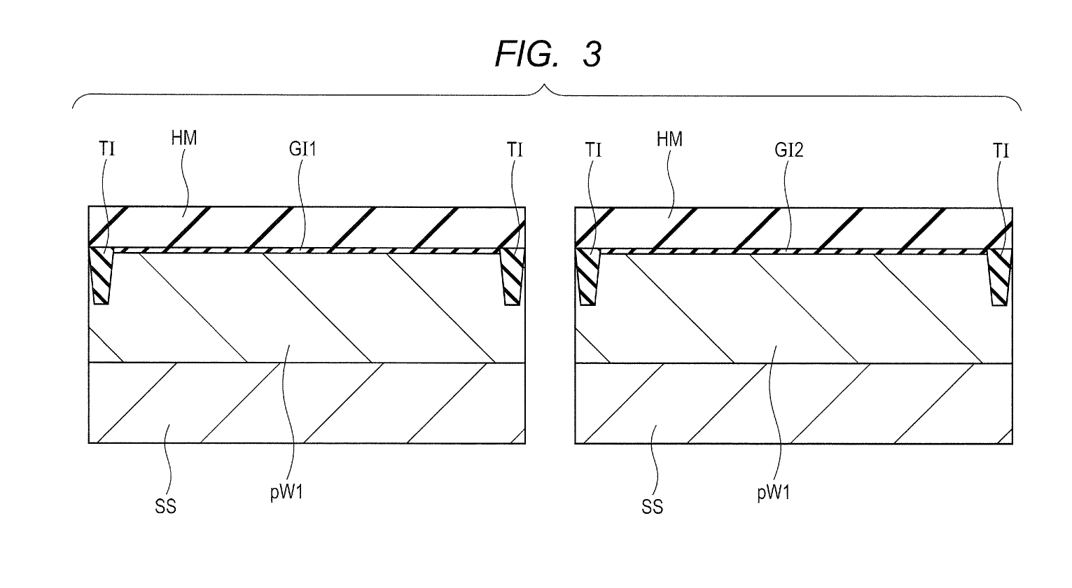

FIG. 3 is a fragmentary cross-sectional view of the semiconductor substrate during a manufacturing step of the semiconductor device following that of FIG. 2;

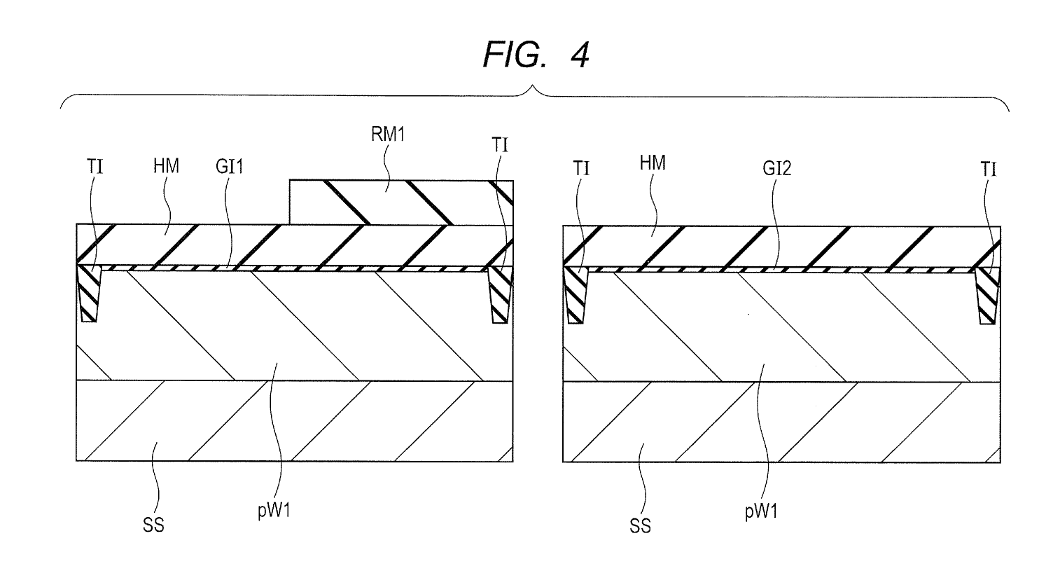

FIG. 4 is a fragmentary cross-sectional view of the semiconductor substrate during a manufacturing step of the semiconductor device following that of FIG. 3;

FIG. 5 is a fragmentary cross-sectional view of the semiconductor substrate during a manufacturing step of the semiconductor device following that of FIG. 4;

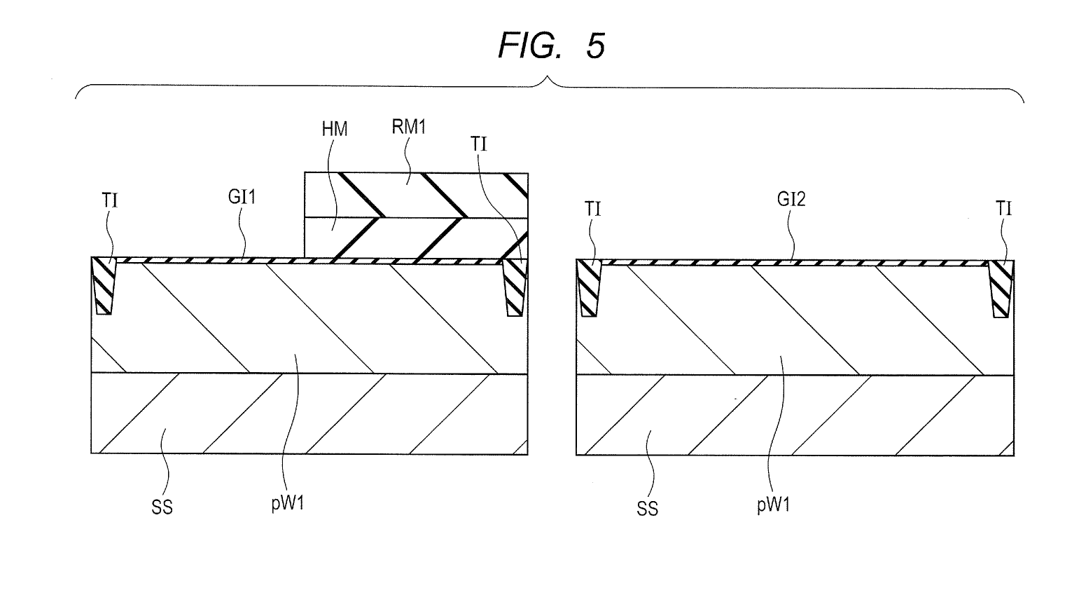

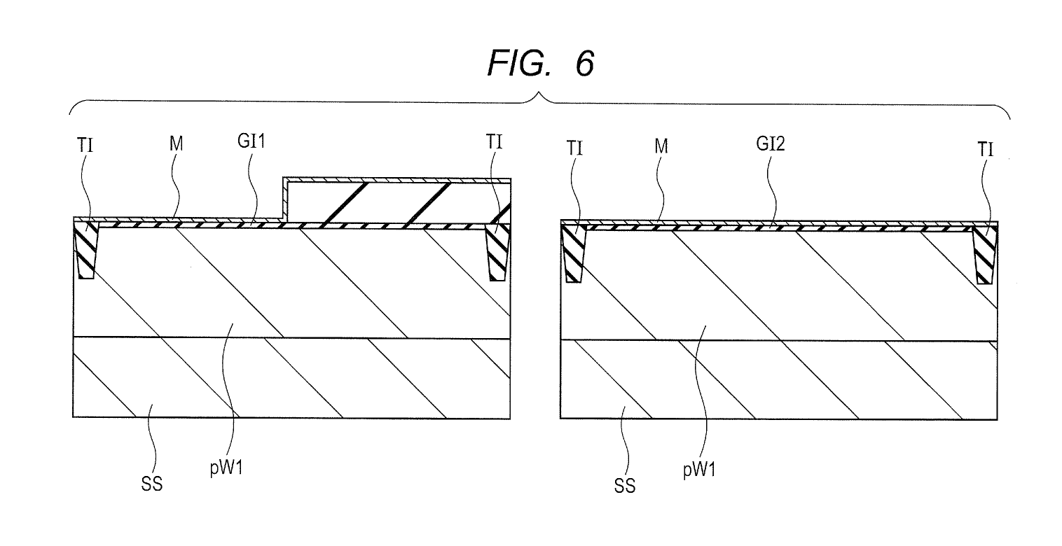

FIG. 6 is a fragmentary cross-sectional view of the semiconductor substrate during a manufacturing step of the semiconductor device following that of FIG. 5;

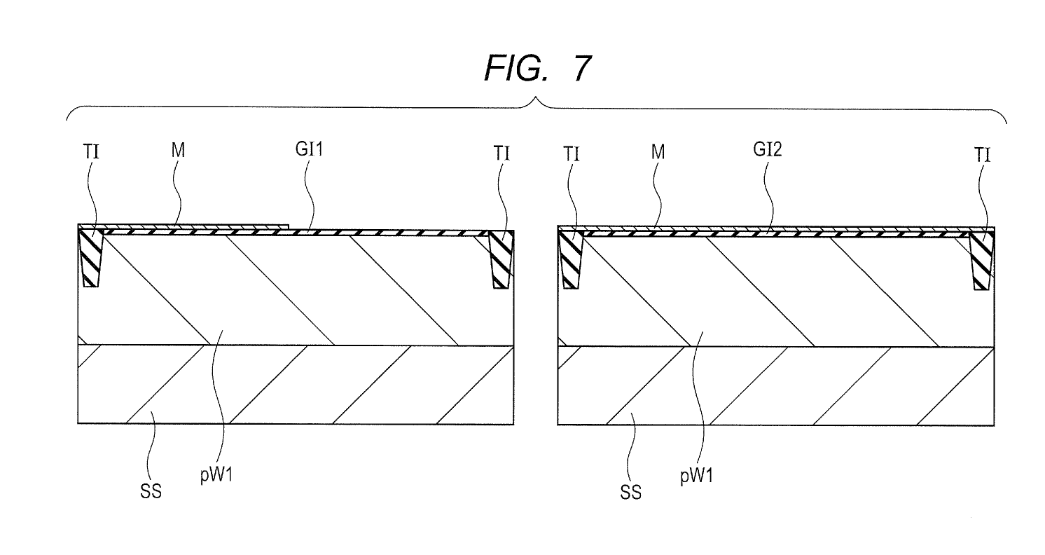

FIG. 7 is a fragmentary cross-sectional view of the semiconductor substrate during a manufacturing step of the semiconductor device following that of FIG. 6;

FIG. 8 is a fragmentary cross-sectional view of the semiconductor substrate during a manufacturing step of the semiconductor device following that of FIG. 7;

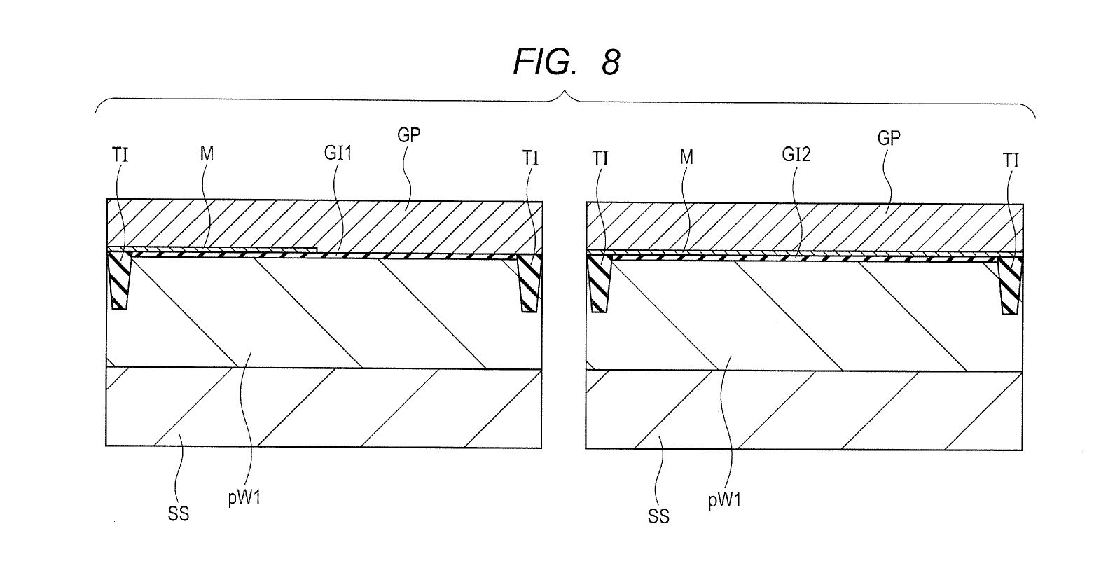

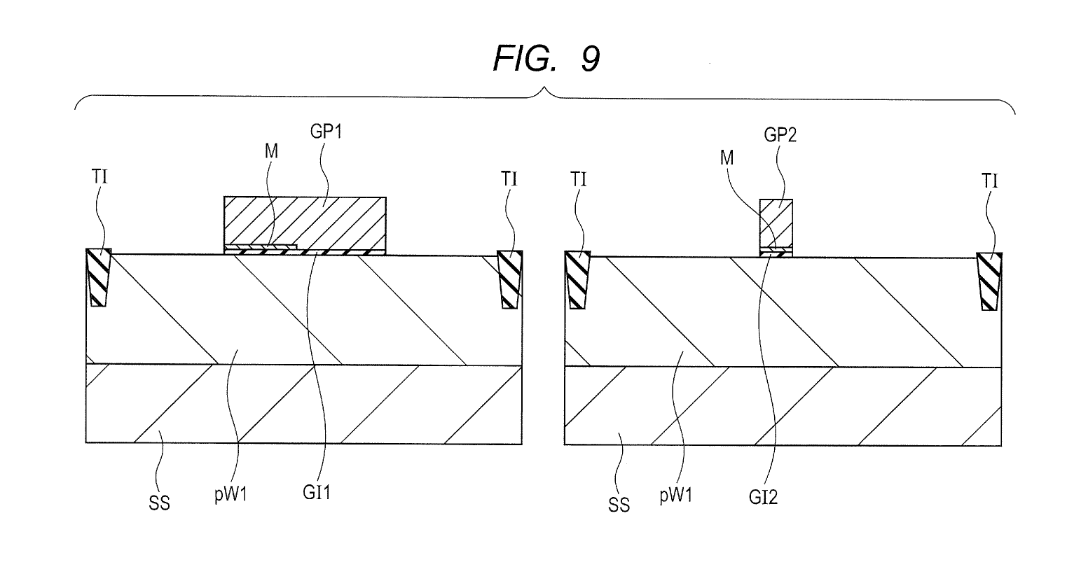

FIG. 9 is a fragmentary cross-sectional view of the semiconductor substrate during a manufacturing step of the semiconductor device following that of FIG. 8;

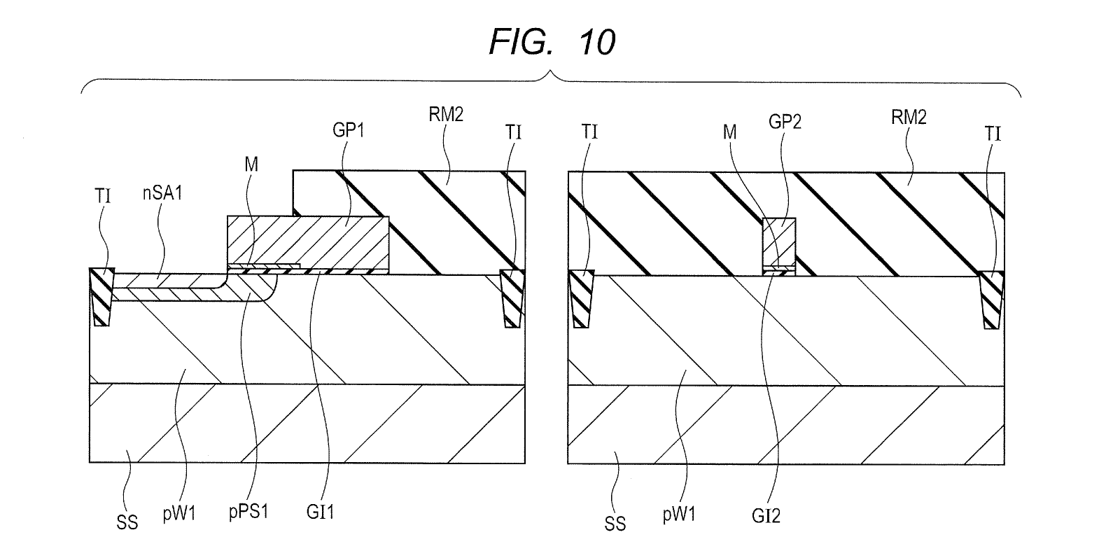

FIG. 10 is a fragmentary cross-sectional view of the semiconductor substrate during a manufacturing step of the semiconductor device following that of FIG. 9;

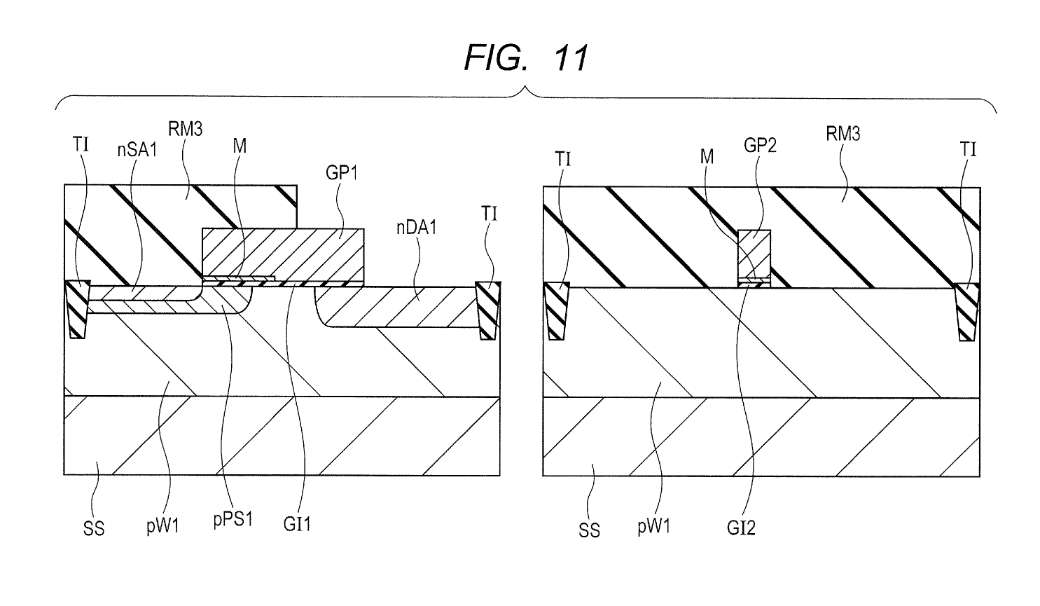

FIG. 11 is a fragmentary cross-sectional view of the semiconductor substrate during a manufacturing step of the semiconductor device following that of FIG. 10;

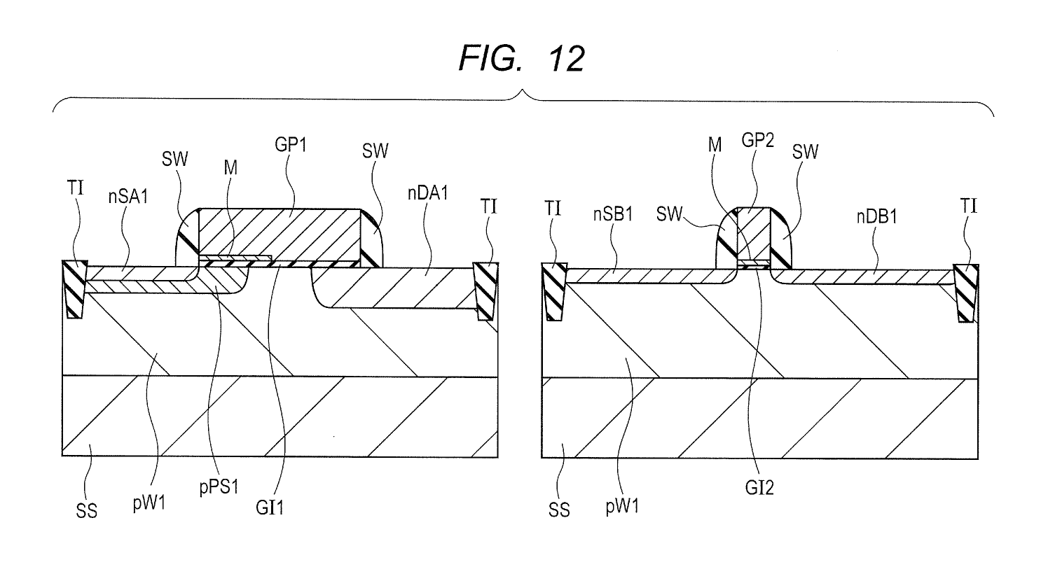

FIG. 12 is a fragmentary cross-sectional view of the semiconductor substrate during a manufacturing step of the semiconductor device following that of FIG. 11;

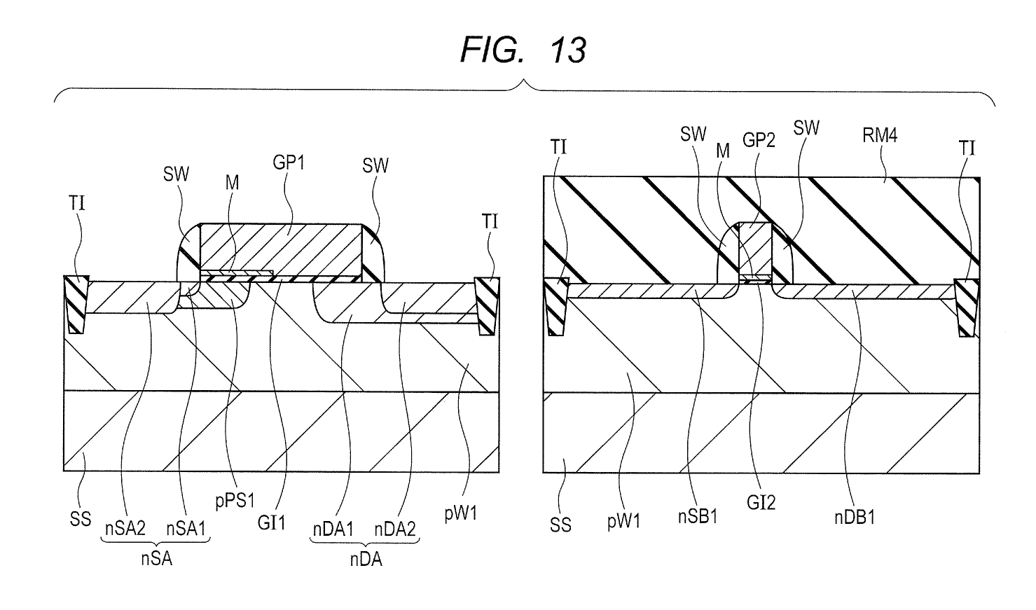

FIG. 13 is a fragmentary cross-sectional view of the semiconductor substrate during a manufacturing step of the semiconductor device following that of FIG. 12;

FIG. 14 is a fragmentary cross-sectional view of the semiconductor substrate during a manufacturing step of the semiconductor device following that of FIG. 13;

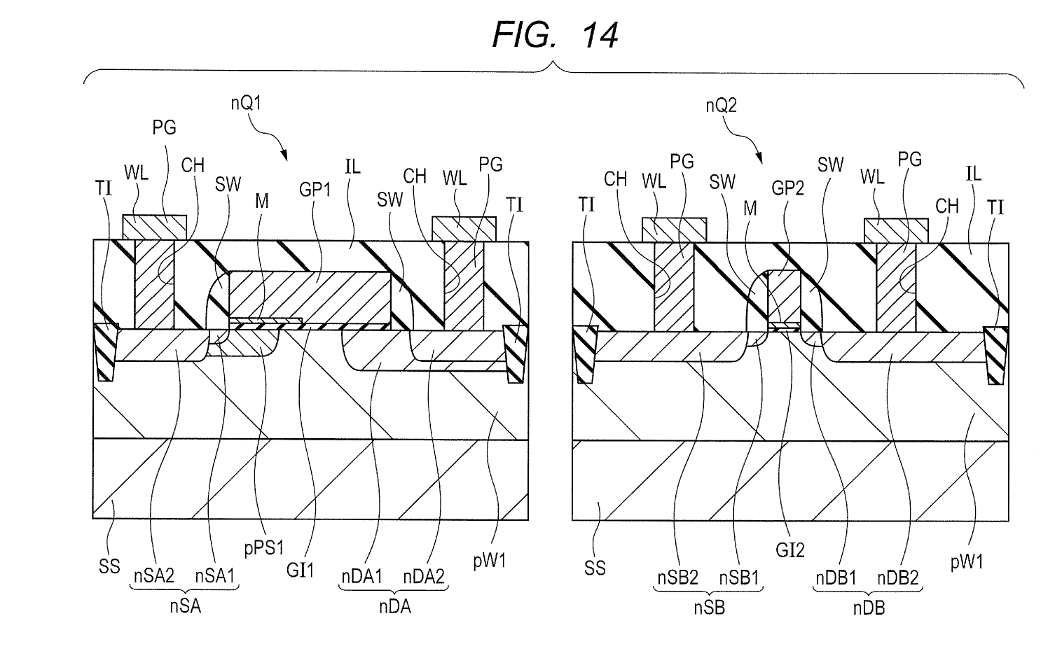

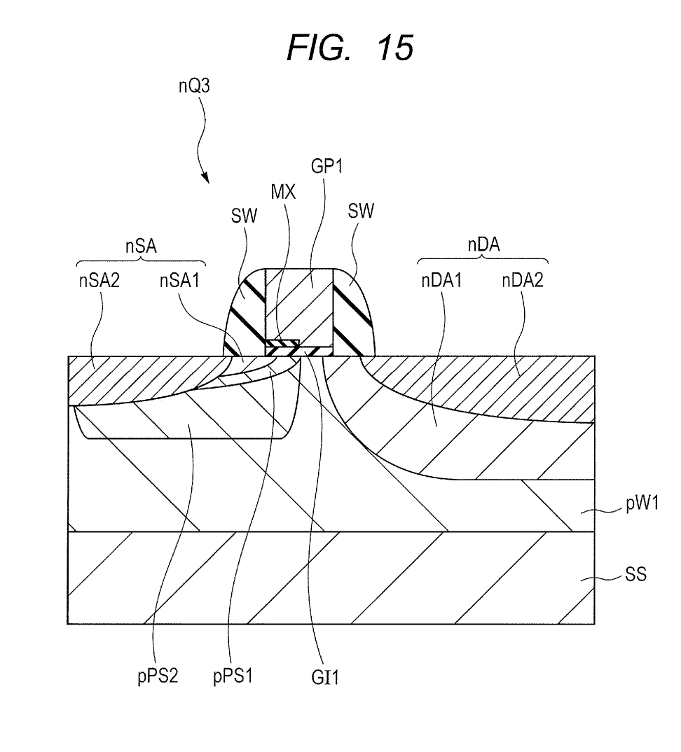

FIG. 15 is a fragmentary cross-sectional view of a semiconductor device according to another embodiment;

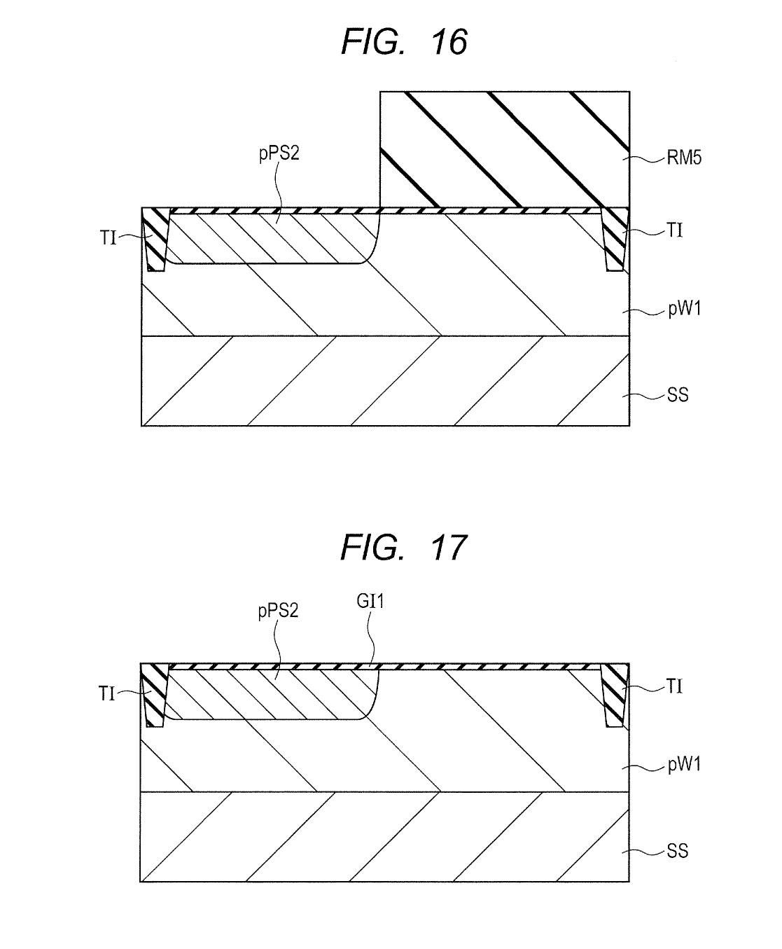

FIG. 16 is a fragmentary cross-sectional view of a semiconductor substrate during a manufacturing step of the semiconductor device of FIG. 15;

FIG. 17 is a fragmentary cross-sectional view of the semiconductor substrate during a manufacturing step of the semiconductor device following that of FIG. 16;

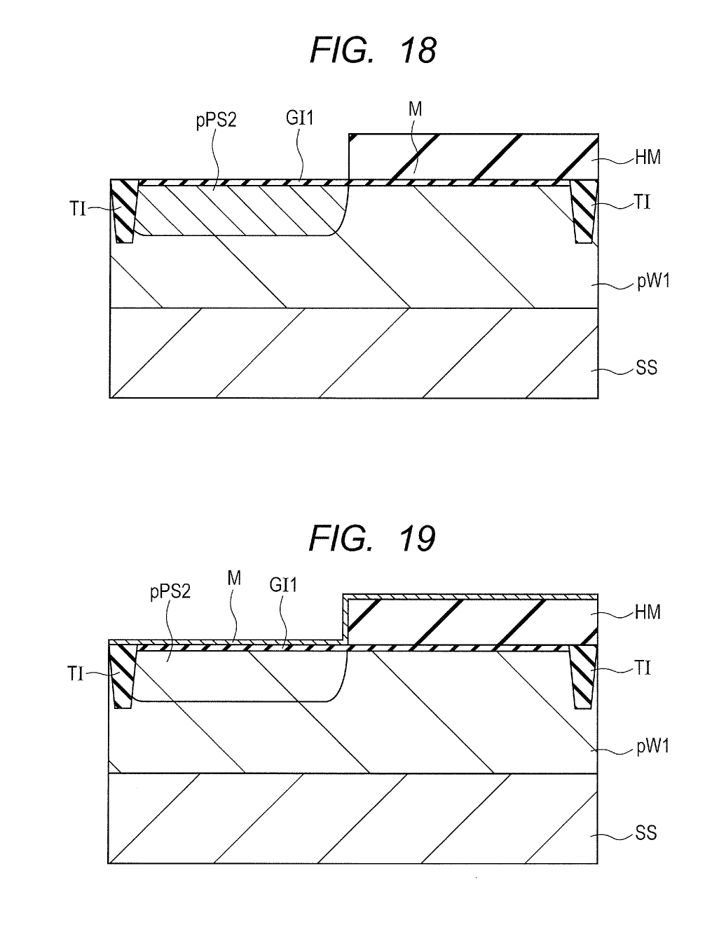

FIG. 18 is a fragmentary cross-sectional view of the semiconductor substrate during a manufacturing step of the semiconductor device following that of FIG. 17;

FIG. 19 is a fragmentary cross-sectional view of the semiconductor substrate during a manufacturing step of the semiconductor device following that of FIG. 18;

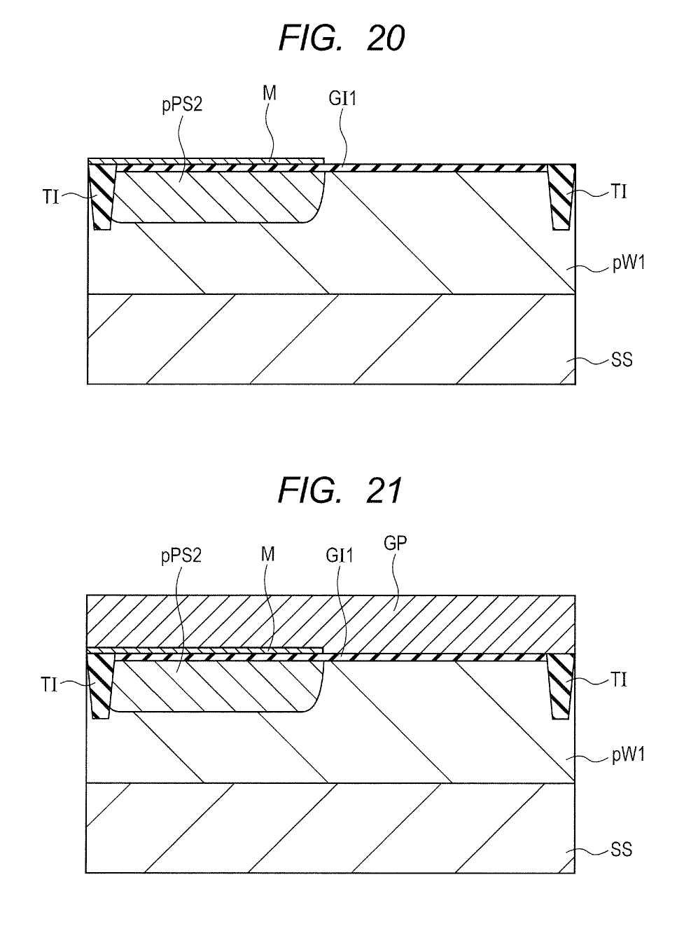

FIG. 20 is a fragmentary cross-sectional view of the semiconductor substrate during a manufacturing step of the semiconductor device following that of FIG. 19;

FIG. 21 is a fragmentary cross-sectional view of the semiconductor substrate during a manufacturing step of the semiconductor device following that of FIG. 20;

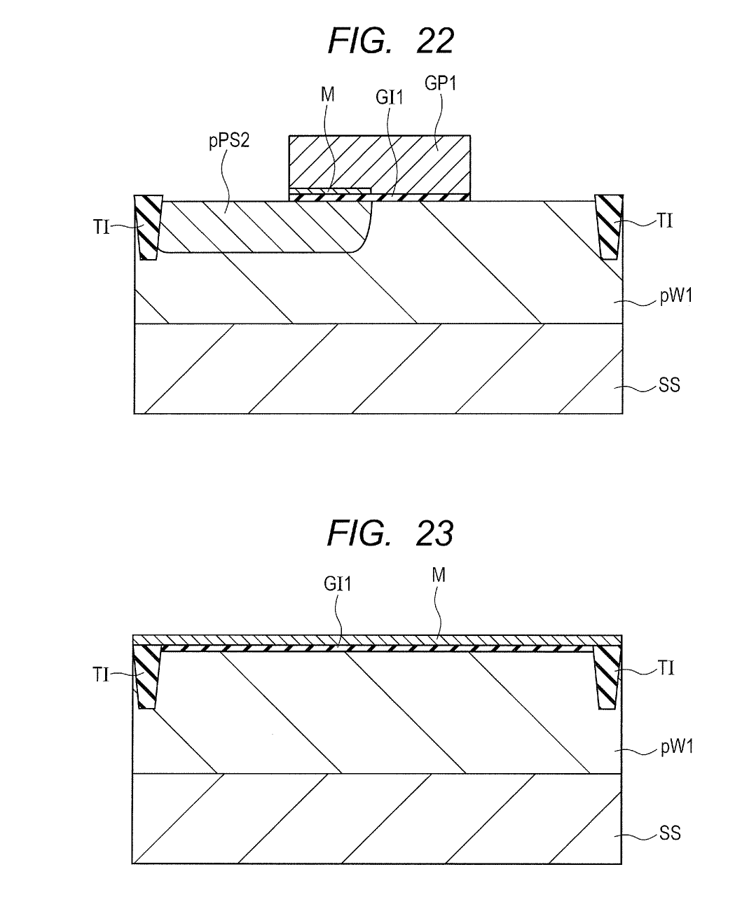

FIG. 22 is a fragmentary cross-sectional view of the semiconductor substrate during a manufacturing step of the semiconductor device following that of FIG. 21;

FIG. 23 is a fragmentary cross-sectional view during a manufacturing step of a semiconductor device according to a further embodiment;

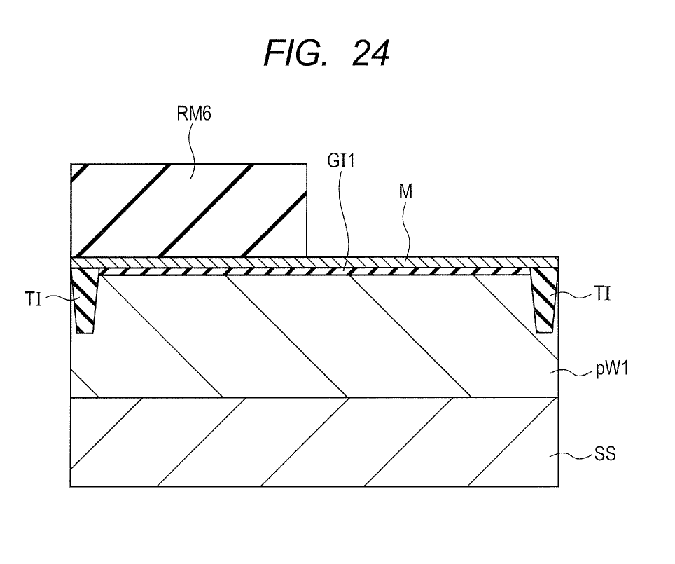

FIG. 24 is a fragmentary cross-sectional view of a semiconductor substrate during a manufacturing step of the semiconductor device following that of FIG. 23;

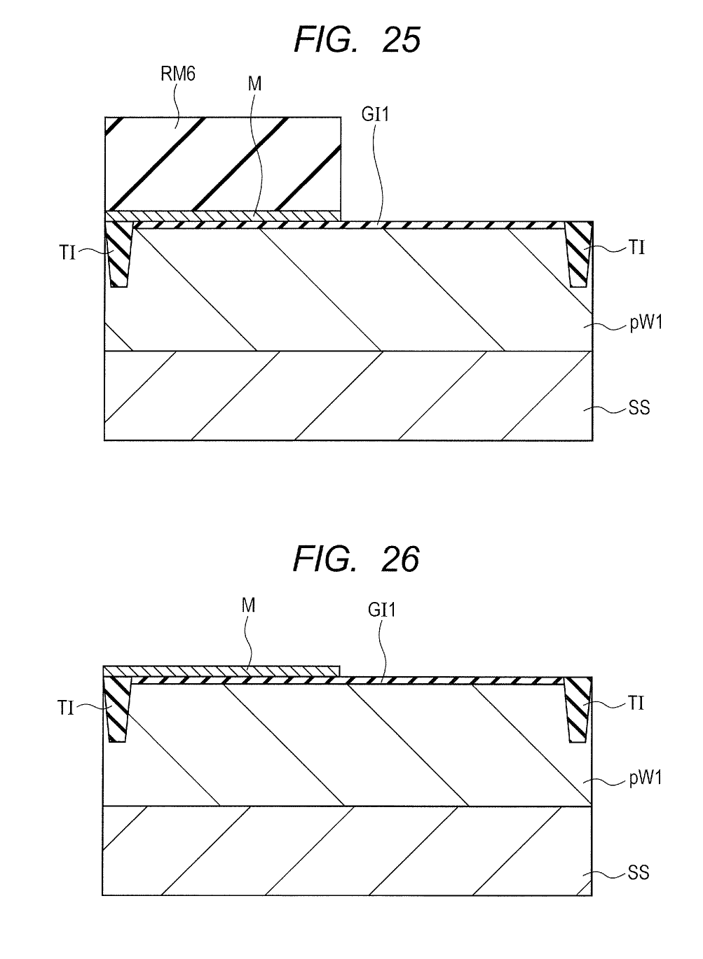

FIG. 25 is a fragmentary cross-sectional view of the semiconductor substrate during a manufacturing step of the semiconductor device following that of FIG. 24;

FIG. 26 is a fragmentary cross-sectional view of the semiconductor substrate during a manufacturing step of the semiconductor device following that of FIG. 25;

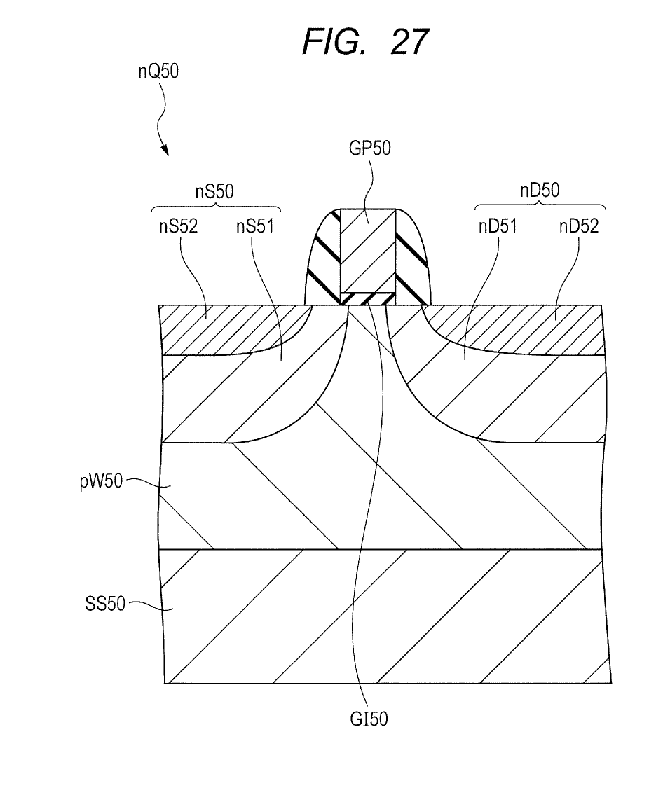

FIG. 27 is a fragmentary cross-sectional view of an insulating gate field effect transistor investigated by the present inventors;

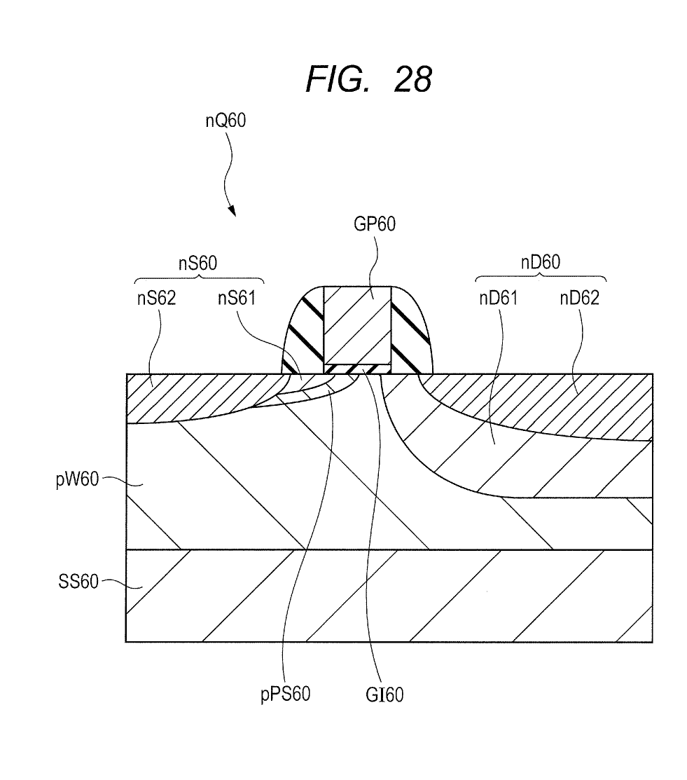

FIG. 28 is a fragmentary cross-sectional view of another insulating gate field effect transistor investigated by the present inventors;

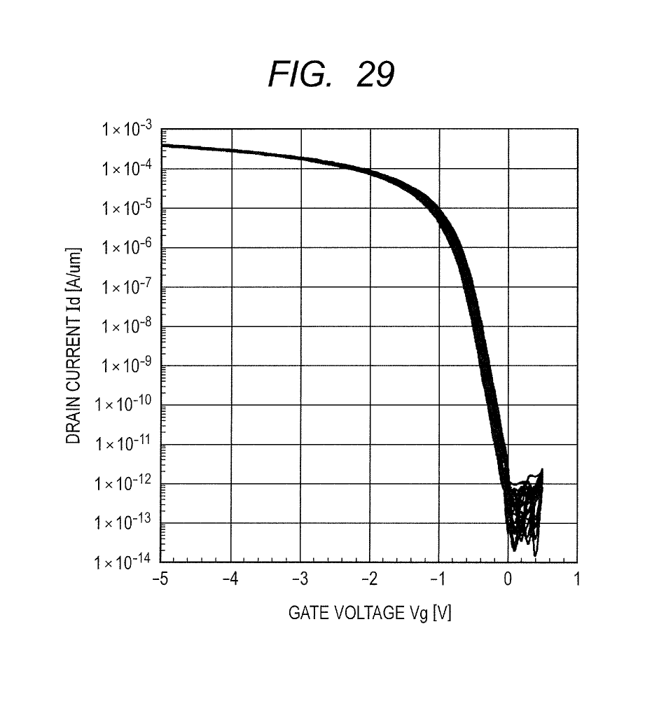

FIG. 29 is a graph showing the relationship between a drain current Id and a gate voltage Vg when the impurity concentration of a p⁺ type semiconductor region for punch-through stopper is relatively low; and

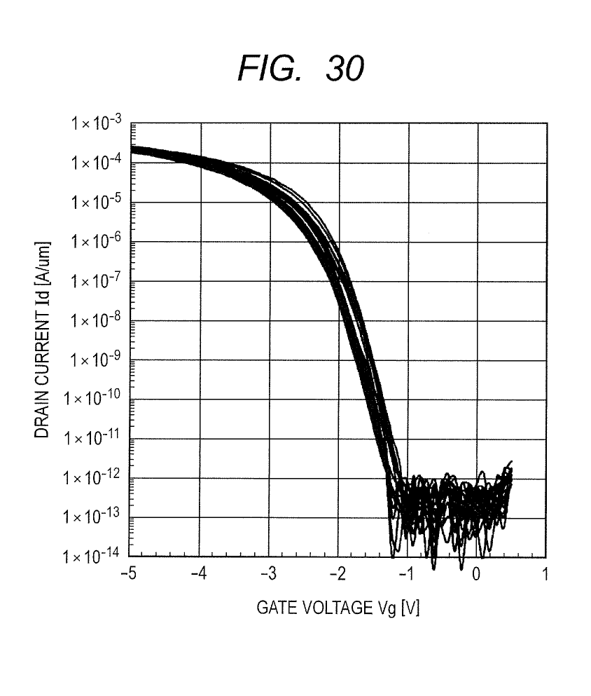

FIG. 30 is a graph showing the relationship between a drain current Id and a gate voltage Vg when the impurity concentration of a p⁺ type semiconductor region for punch-through stopper is relatively high.

### DETAILED DESCRIPTION

In the below-described embodiments, a description will be made after divided into a plurality of sections or embodiments if necessary for convenience sake. They are not independent from each other, but in a relation such that one is a modification example, details, a complementary description, or the like of a part or whole of the other one unless otherwise specifically indicated. And, in the below-described embodiments, when a reference is made to the number of elements (including the number, value, amount, range, or the like), the number is not limited to a specific number but may be more than or less than the specific number, unless otherwise specifically indicated or principally apparent that the number is limited to the specific number. Further, in the below-described embodiments, it is needless to say that the constituent elements (including element steps or the like) are not always essential unless otherwise specifically indicated or principally apparent that they are essential. Similarly, in the below-described embodiments, when a reference is made to the shape, positional relationship, or the like of the constituent elements, that substantially approximate or similar to it is also embraced unless otherwise specifically indicated or principally apparent that it is not. This also applies to the above-described value and range.

Embodiments will hereinafter be described in detail referring to drawings. In all the drawings for describing the below-described embodiments, members of a like function will be identified by like reference numerals and overlapping descriptions will be omitted. In the below-described embodiments, a repeated description of the same or like parts will be omitted in principle unless particularly necessary.

In the description described below, MISFET (metal insulator semiconductor field effect transistor) is abbreviated as MIS; an n channel MISFET is abbreviated as nMIS; and a p channel MISFET is abbreviated as pMIS.

### First Embodiment

FIG. 27 is a fragmentary cross-sectional view of an insulating gate field effect transistor investigated by the present inventors. It is to be noted that a high breakdown voltage nMIS nQ50 is shown in this drawing as one example of the insulating gate field effect transistor.

The nMIS nQ50 is equipped with a gate insulating film GI50 formed on a p well pW50 of a semiconductor substrate SS50, a gate electrode GP50 formed on the gate insulating film, and n type source region nS50 and drain region nD50 formed in the p well pW50 on both sides, in a gate length direction (shorter direction), of the gate electrode GP50.

The source region nS50 and the drain region nD50 are equipped with first regions nS51 and nD51 for LDD and second regions nS52 and nD52 embraced in and electrically coupled to them, respectively. The impurity concentration of the first regions nS51 and nD51 for LDD is set lower than the impurity concentration of the second regions nS52 and nD52.

In the nMIS nQ50 structure shown in FIG. 27, however, when the gate length is reduced, there is a possibility of punch-through occurring due to expansion of a depletion layer at a pn junction between each of the first regions nS51 and nD51 for LDD and the p well pW50. At the same time, there is a possibility of an ON-state current increasing and impact ions induced thereby increasing.

A MIS nQ60 structure shown in FIG. 28 is therefore proposed to overcome the above-mentioned problem. The nMIS nQ60 is equipped with a gate insulating film GI60 formed on a p well PW60 of a semiconductor substrate SS60, a gate electrode GP60 formed on the p well, and n type source region nS60 and drain region nD60 formed in the p well pW60 on both sides, in the gate length direction, of the gate electrode GP60.

The source region nS60 and the drain region nD60 are unsymmetrical. The source region nS60 has a first region nS61 for LDD and a second region nS62 electrically coupled thereto. The first region nS61 for LDD is formed between the gate electrode GP60 and the second region nS62. This first region nS61 for LDD has, below the end portion thereof on the side of a channel, a p⁺ type semiconductor region pPS60 for punch-through stopper.

On the other hand, the drain region nD60 has a first region nD61 for LDD and a second region nD62 embraced therein and electrically coupled thereto. The impurity concentration of the first regions nS61 and nD61 for LDD is set lower than the impurity concentration of the second regions nS62 and nD62.

In this nMIS nQ60, the first regions nS61 and nD61 are formed with different masks. This makes it possible to increase the impurity concentration of the p⁺ type semiconductor region pPS60 for punch-through stopper and in addition, decrease the junction depth of the first region nS61 on the side of the source region nS60. As a result, a depletion layer hardly extends toward the side of the source region nS60, by which occurrence of punch-through between source and drain is suppressed.

In the nMIS nQ60 structure shown in FIG. 28, the threshold voltage thereof is determined by the p⁺ type semiconductor region pPS60 for punch-through stopper. The punch-through problem hardly occurs at a gate length of MIS within a range of from 0.5 μm to 1.0 μm, but it occurs at a gate length not greater than 0.5 μm due to a short channel effect, which however differs depending on conditions and therefore cannot be suggested generally. In order to keep short-channel characteristics, it is necessary to increase the impurity concentration of the p⁺ type semiconductor region pPS60 for punch-through stopper.

FIG. 29 and FIG. 30 show the relationships between a drain current Id and a gate voltage Vg when the impurity concentration of the p⁺ type semiconductor region pPS60 for punch-through stopper is relatively low and relatively high, respectively.

As is apparent from FIG. 29, when the impurity concentration of the p⁺ type semiconductor region pPS60 for punch-through stopper is low, in-plane variations of the Id-Vg curve are small, while as shown in FIG. 30, when the impurity concentration of the p⁺ type semiconductor region pPS60 for punch-through stopper is high, in-plane variations of the Id-Vg curve become large. Thus, there occur variations in the threshold voltage when regulation of the threshold voltage of MIS is tried only by changing the setting of the impurity concentration of the p⁺ type semiconductor region pPS60 for punch-through stopper.

Next, the structure of a semiconductor device of First Embodiment will be described referring to FIG. 1. FIG. 1 is a fragmentary cross-sectional view of the semiconductor device of First embodiment. In the following description, nMIS (first insulating gate field effect transistor) nQ1 will be described as one example of an insulating gate field effect transistor. The description however can also be applied to pMIS.

A semiconductor substrate (which will hereinafter be called “substrate” simply) SS is made of, for example, p⁻ type or n⁻ type single crystal silicon and it has, on the main surface side thereof, a p well pW1. The p well pW1 has been doped with an impurity such as boron (B) or boron difluoride (BF₂). The impurity concentration of the p well pW1 is set higher than the impurity concentration of the substrate SS.

This substrate SS has an nMIS nQ1. The nMIS nQ1 has a gate insulating film GI1, a gate electrode GP1, an n type source region nSA, and an n type drain region nDA. The nMIS nQ1 has a gate length of, for example, 0.5 μm or less, more specifically, for example, about 0.2 μm.

The gate insulating film GI1 is made of, for example, silicon oxynitride (SiON) or silicon oxide (SiO) and is formed on the p well pW1. This gate insulating film GI1 has thereon a gate electrode GP1 made of, for example, p type or n type polycrystalline silicon. These gate insulating film GI1 and gate electrode GP1 have, on the side surface thereof, a sidewall SW made of, for example, silicon oxide (SiO).

The p well PW1 of the substrate SS has n type source region nSA and drain region nDA on both sides, in the gate length direction (shorter direction), of the gate electrode GP1, respectively.

The n type source region nSA has an n⁻ type first region nSA1 and an n⁺ type second region nSA2. The first region nSA1 extends from a position below the end portion of the gate electrode GP1 and a position reaching the second region nSA2 and is electrically coupled to the second region nSA2. These first region nSA1 and second region nSA2 have been doped with an impurity such as phosphorus (P) or arsenic (As).

The first region nSA1 is an LDD region for relaxing an electric field and thereby suppressing or preventing generation of hot carriers and it has an impurity concentration lower than the impurity concentration of the second region nSA2. The impurity concentration of the first region nSA1 is, for example, about 1×10¹³/cm² (1×10¹⁸/cm³). The impurity concentration of the second region nSA2 is, for example, about 1×10¹⁵/cm² (1×10²⁰/cm³).

The first region nSA1 has therebelow a p⁺ type semiconductor region (first semiconductor region) pPS1 so as to cover therewith the end portion of the first region nSA1 on the side of the gate electrode GP1. This semiconductor region pPS1 is a punch-through stopper region for suppressing a depletion layer from extending in a lateral direction in the p well pW1 rightly below the gate electrode GP1 and thereby suppressing or preventing occurrence of punch-through. This semiconductor region pPS1 has been doped with, for example, boron. The impurity concentration of the semiconductor region pPS1 is higher than the impurity concentration of the p well pW1 and is, for example, about 5×10¹²/cm² (5×10¹⁷/cm³).

The above-mentioned n type drain region nDA has an n⁻ type first region nDA1 and an n⁺ type second region nDA2. The first region nDA1 extends to a position deeper than the first region nSA1 on the side of the source region nSA. This first region nDA1 embraces therein the second region nDA2 and the first region nDA1 and the second region nDA2 are electrically coupled to each other. These first region nDA1 and second region nDA2 have been doped with an impurity such as phosphorus (P) or arsenic (As).

The first region nDA1 is the above-described LDD region and the impurity concentration of it is set lower than the impurity concentration of the second region nDA2. The impurity concentration of the first region nDA1 is, for example, about 1×10¹³/cm² (1×10¹⁸/cm³). The impurity concentration of the second region nDA2 is, for example, about 1×10¹⁵/cm² (1×10²⁰/cm³).

The above-mentioned LDD structure may be replaced with an extension structure. The extension structure is suited for miniaturization of devices because in this structure, the mobility of carriers can be enhanced due to the impurity concentration of the first regions nSA1 and nDA1 higher than that in the LDD structure and moreover, the junction depth is smaller than that in the LDD structure.

In such nMIS nQ1 of the semiconductor device of First Embodiment, the gate insulating film GI1 and the gate electrode GP1 have a metal oxide film MX in a portion, on the side of the source region nSA, between them. This means that the gate electrode GP1 of the nMIS nQ1 and the substrate SS have therebetween a film stack portion of the gate insulating film GI1 and the metal oxide film MX and a single film portion of the gate insulating film GI1 along the gate length direction.

This metal oxide film MX is made of, for example, hafnium oxide (HfO) and has a thickness of, for example, from about 0.5 to 1 nm. This metal oxide film MX is provided so as to be located above the p⁺ type semiconductor region pPS1 for punch-through stopper. Here, the metal oxide film MX extends to a position midway, in the gate length direction, between the side surface of the gate electrode GP1 (side surface on the side of the source region nSA) and the gate electrode GP1 and is provided so as to cover the entire semiconductor region pPS1 below the gate electrode GP1.

Since such a metal oxide film MX is provided, it is possible to change the work function of the nMIS nQ1 on the side of the gate electrode GP1 and also change the flat band voltage. Here, the provision of the metal oxide film contributes to, for example, increase in work function and also increase in flat band voltage.

This means that the threshold voltage of the nMIS nQ1 can be regulated without depending on the regulation of the impurity concentration of the semiconductor region pPS1. Here, for example, the threshold voltage of the nMIS nQ1 can be increased without increasing the impurity concentration of the semiconductor region pPS1. Without the metal oxide film M, the impurity concentration of the semiconductor region pPS1 is, for example, 1×10¹³/cm² (10¹⁸/cm³). When the metal oxide film MX is provided, on the other hand, the impurity concentration of the semiconductor region pPS1 can be reduced to, for example, about 5×10¹²/cm² (5×10¹⁷/cm³). As a result, variations in the threshold voltage of the nMIS nQ1 can be reduced and therefore the nMIS nQ1 can have improved operation stability.

In addition, the impurity concentration of the semiconductor region pPS1 in the channel region of the nMIS nQ1 can be reduced so that the mobility of carriers can be improved. Therefore, the nMI SnQ1 can have improved operation speed.

When the metal oxide film MX is provided also on the side of the drain region nDA, there is a possibility of hot carriers generated at the end portion of the drain region nDA being easily injected into the side of the gate electrode GP1 and causing deterioration in reliability (TDDB: time dependent dielectric breakdown and the like) resulting from gate leakage. In order to avoid this, a metal content between the gate insulating film and the gate electrode GP1 should be decreased as much as possible. In First embodiment, therefore, the metal oxide film MX is provided in a portion on the side of the source region nSA effective for suppressing a threshold voltage, while the gate insulating film GI1 remains as a single film without stacking the metal oxide film MX thereover on the side of the drain region nDA. This makes it possible to reduce the above-mentioned variations of a threshold voltage and secure reliability of the nMIS nQ1 at the same time.

When hafnium oxide is used as a material of the metal oxide film MX, it can improve the controllability of a flat band voltage and in addition, improve the uniformity of an in-plane thickness of the metal oxide film MX. Moreover, when hafnium oxide is used as a material of the metal oxide film MX and it is used for pMIS, it can reduce the gate work function. Therefore, the threshold voltage of both the nMIS and pMIS can be regulated by using only one material for them.

As the material of the metal oxide film MX, for example, titanium oxynitride (TiON) or aluminum oxide (AlO) may be used instead. Such a film is also useful for regulating the threshold voltage. Hafnium oxide and titanium oxynitride may be used for both the nMIS and pMIS, but aluminum oxide is preferably used for the nMIS.

Next, one example of a method of manufacturing the semiconductor device of First embodiment will be described referring to FIGS. 2 to 14. FIGS. 2 to 14 are fragmentary cross-sectional views of the substrate SS during manufacturing steps of the semiconductor device of First Embodiment. In FIGS. 2 to 14, a fragmentary cross-sectional view of an input/output circuit region of the semiconductor device is shown on the left side, while a fragmentary cross-sectional view of an internal circuit region of the semiconductor device is shown on the right side. To facilitate understanding of the description, only the formation steps of the nMIS will be described without describing the formation steps of the pMIS.

As shown in FIG. 2, after formation of a p well PW1 in the substrate SS, a trench type isolation TI is formed in the main surface of the substrate SS. The MIS formation region of the p well pW1 has, introduced therein, an impurity for regulating the threshold voltage of various MISs.

Then, in an element formation region surrounded with the trench isolation TI in the main surface of the semiconductor substrate SS, two gate insulating films GI1 and GI2 different in thickness are formed. Although the gate insulating films GI1 and GI2 are made of the same material, for example, silicon oxynitride or silicon oxide, the gate insulating film GI2 in the internal circuit region is made thinner than the gate insulating film GI1 in the input/output circuit region.

Then, as shown in FIG. 3, a hard mask HM is deposited on the main surface of the substrate SS by a CVD (chemical vapor deposition) process or the like. The hard mask film HM is a mask for selectively attaching a trace amount of a metal film for the formation of the metal oxide film MX (refer to FIG. 1) onto the substrate SS. This hard mask film HM is made of, for example, TEOS (tetraethoxysilane), silicon nitride (SiN), or titanium nitride (TiN) and has a thickness of, for example, from about 5 to 30 nm.

Next, as shown in FIG. 4, a pattern of a resist film RM1 is formed on the hard mask film HM by photolithography. The pattern of the resist film RM1 is formed so as to expose the formation region of the metal oxide film MX (refer to FIG. 1) and cover the other region.

Then, as shown in FIG. 5, with the resist film RM1 as an etching mask, the hard mask film HM is etched to form a pattern of the hard mask film HM. This pattern of the hard mask film HM is formed so as to expose the formation region of the metal oxide film MX (refer to FIG. 1) and cover the other region. As etching, not dry etching but wet etching is used from the standpoint of securing the reliability of the gate insulating films GI1 and GI2.

Next, after removal of the resist film RM1, a metal film M such as hafnium (Hf) film is deposited on the main surface of the substrate SS by using a CVD process or an atomic layer deposition (ALD) process. The metal film M has a thickness of, for example, from about 0.5 to 1 nm. Another metal film such as titanium nitride (TiN) or aluminum (Al) film may be deposited instead of hafnium.

Then, the hard mask film HM is removed by etching to selectively remove the metal film M on the hard mask film HM (lift-off process). By this removal, as shown in FIG. 7, a pattern of the metal film M is formed so as to cover the entirety of the source region and a portion of the gate electrode of the nMIS in the input/output circuit region, while a pattern of the metal film M is formed so as to cover the entirety in the internal circuit region. In the present embodiment, by using a lift-off process for the formation of the pattern of the metal film M, a pattern of the metal film M can be formed with a small thickness without damaging the gate insulating film GI1. A trace amount of the metal oxide film MX (refer to FIG. 1) can therefore be formed between the gate insulating film GI1 and the gate electrode GP1.

Then, as shown in FIG. 8, after deposition of a gate electrode formation film GP made of, for example, polycrystalline silicon on the main surface of the substrate SS by using a CVD process or the like, the resulting film is patterned using a dry etching process or the like with a resist film (not illustrated) as an etching mask. As a result, as shown in FIG. 9, a gate electrode GP1 for nMIS of an input/output circuit is formed in the input/output circuit region and a gate electrode GP2 for nMIS of an internal circuit is formed in the internal circuit region.

In the nMIS region of the input/output circuit, the metal film M is formed, in a portion on the side of the source region, between the gate insulating film GI1 and the gate electrode GP1. On the other hand, in the nMIS region of the internal circuit, the metal film M is formed in the entire region between the gate insulating film GI2 and the gate electrode GP2. The gate electrode GP2 for the nMIS of the internal circuit is formed with a gate length shorter than that of the gate electrode GP1 for the nMIS of the input/output circuit.

Next, as shown in FIG. 10, a pattern of a resist film RM2 is formed using photolithography on the main surface of the substrate SS. The pattern of the resist film RM2 is formed so as to expose the nMIS of the input/output circuit region on the side of the source region and to cover the other region.

Then, with the resist film RM2 and the gate electrode GP1 as masks, an impurity such as phosphorus or arsenic is implanted into the main surface of the substrate SS by using an ion implantation process or the like to form an n⁻ type first region nSA1 in the source region of the nMIS of the input/output circuit region. At the time of impurity implantation, impurity ions are injected vertically relative to the main surface of the substrate SS.

Then, with the resist film RM2 and the gate electrode GP1 as a mask, an impurity such as boron is implanted into the main surface of the substrate SS by using an ion implantation process or the like to form a p⁺ type semiconductor region pPS1 for punch-through stopper in the nMIS of the input/output circuit region on the side of the source region. This semiconductor region pPS1 is formed with a junction depth greater than that of the first region nSA1 and it embraces the first region nSA1.

At the time of this impurity implantation, impurity ions are implanted obliquely relative to the main surface of the substrate SS, by which the end portion of the semiconductor region pPS1 (end portion on the side of the gate electrode GP1) enters the p well PW1 below the gate electrode GP1 on the side of the end portion thereof. It is to be noted that the ion implantation step of the first region nSA1 and the ion implantation step of the semiconductor region pPS1 may be conducted in reverse order.

Next, after removal of the resist film RM2, a pattern of a resist film RM3 is formed on the main surface of the substrate SS by using photolithography, as shown in FIG. 11. The pattern of the resist film RM3 is formed so as to expose the drain region of the nMIS of the input/output circuit region while covering the other region.

Then, with the resist film RM3 and the gate electrode GP1 as a mask, an impurity such as phosphorus or arsenic is implanted into the main surface of the substrate SS by using an ion implantation process or the like to form an n⁻ type first region nDA1 in the drain region of the nMIS of the input/output circuit region. The first region nDA1 is formed with a depth greater than that of the n⁻ type first region nSA1 on the side of the source region.

At the time of this impurity implantation, impurity ions are implanted obliquely relative to the main surface of the substrate SS, by which the end portion of the first region nDA1 (end portion on the side of the gate electrode GP1) enters the p well PW1 below the electrode GP1 on the end portion thereof.

Next, after removal of the resist film RM3, n⁻ type first regions nSB1 and nDB1 for LDD source and drain of the nMIS are formed in the internal circuit region as shown in FIG. 12. After deposition of an insulating film such as silicon oxide (SiO) by using a CVD process or the like on the main surface of the substrate SS, the insulating film is etched back using a dry etching process to form a sidewall SW on the side surface of the gate electrodes GP1 and GP2.

Next, as shown in FIG. 13, a pattern of a resist film RM4 is formed on the main surface of the substrate SS by using photolithography. The pattern of the resist film RM4 is formed so as to expose the nMIS formation region of the input/output circuit region, while covering the other region.

Then, with the resist film RM4 as a mask, an impurity such as phosphorus or arsenic is implanted into the main surface of the substrate SS by using an ion implantation process or the like to form n⁺ type second regions nSA2 and nDA2 for source and drain in the input/output circuit region. At the time of this ion implantation, impurity ions are implanted vertically relative to the main surface of the substrate SS.

Next, after removal of the resist film RM4, n⁺ type second regions nSB2 and nDB2 for source and drain are formed in the internal circuit region as shown in FIG. 14. The second regions nSB2 and nDB2 are formed so that the impurity concentration thereof is higher than that of the first regions nSB1 and nDB1.

After completion of all the impurity ion implantation steps, the substrate SS is subjected to annealing treatment to activate various impurities. At the time of this annealing treatment, the metal film M is oxidized into the metal oxide film MX.

In such a manner, the nMIS nQ1 for the input/output circuit and the nMIS (second insulating gate field effect transistor) nQ2 for the internal circuit are formed on the substrate SS. A power supply voltage (drive voltage) of the nMIS nQ1 for input/output circuit is, for example, about 5V, meaning that it is a high breakdown voltage MIS. On the other hand, a power supply voltage (drive voltage) of the nMIS nQ2 for internal circuit is lower than that of the input/output circuit and is, for example, about 3.3V or lower, meaning that it is a low breakdown voltage MIS. Examples of the input/output circuit include input buffer circuit, output buffer circuit, and a bidirectional buffer circuit. Examples of the internal circuit include arithmetic circuit, control circuit, and counter circuit.

Since in the nMIS nQ1 for input/output circuit, the metal oxide film MX is provided in a portion, on the side of the source region nSA, between the gate insulating film GI1 and the gate electrode GP1, variations in threshold voltage of the nMIS nQ1 for input/output circuit can be reduced so that the nMIS nQ1 for input/output circuit can have improved operation stability. In addition, since the impurity concentration of the semiconductor region pPS1 in the channel region of the nMIS nQ1 for input/output circuit can be reduced and the mobility of carriers can be improved, the nMIS nQ1 for input/output circuit can have an improved operation speed. Moreover, no metal oxide film MX is provided on the side of the drain region nDA so that troubles due to hot carriers at the end of the drain region nDA can be reduced and the nMIS nQ1 for input/output circuit can have stable reliability.

In the nMIS nQ2 for internal circuit, the metal oxide film MX is provided in the entire region between the insulating film GI2 and the gate electrode GP2 so that the concentration of the threshold voltage regulating impurity in the channel region of the nMIS nQ2 can be reduced and thereby the mobility of carriers can be improved. This leads to improvement in the operation speed of the nMIS nQ2 for internal circuit. In addition, in the internal circuit, a power supply voltage is low and therefore troubles due to hot carriers hardly occur at the end of the drain region nDB of the nMIS nQ2 so that even if the metal oxide film MX is provided in the entire region between the gate insulating film GI2 and the gate electrode GP2, it does not cause deterioration in the reliability of the resulting nMIS nQ2.

Then, after formation of an insulating film IL made of, for example, silicon oxide, on the main surface of the substrate SS by using a CVD process or the like, a contact hole CH is formed in the insulating film IL by using a dry etching process or the like. Then, after formation of a plug PG made of a conductor film in the contact hole CH, a wiring WL made of a conductor film is formed on the insulating film IL, which is followed by conventional manufacturing steps to manufacture a semiconductor device.

### Second Embodiment

A structure of a semiconductor device according to Second Embodiment will next be described referring to FIG. 15. FIG. 15 is a fragmentary cross-sectional view of the semiconductor device of Second Embodiment.

In the above-mentioned First Embodiment, the impurity concentration of the p⁺ type semiconductor region pPS1 for punch-through stopper can be decreased, but this decrease in the impurity concentration may cause punch-through at a position deeper than the semiconductor region pPS1.

In an nMIS (first insulating gate field effect transistor) nQ3 according to Second Embodiment, a p type semiconductor region (second semiconductor region) pPS2 for second punch-through stopper is formed at a position lower than a p⁺ type semiconductor region pPS1 for first punch-through stopper. This semiconductor region pPS2 has been doped, for example, with boron. The impurity concentration of the semiconductor region pPS2 is set smaller than that of the semiconductor region pPS1 but greater than that of the p well pW1. In addition, the peak region of the impurity concentration of the semiconductor region pPS2 is formed at a position deeper than the peak region of the impurity concentration of the semiconductor region pPS1.

Thus, in the nMIS nQ3 according to Second Embodiment, the p type semiconductor region pPS2 is formed at a position deeper than the p⁺ type semiconductor region pPS1 so that a depletion layer can be prevented from extending in the lateral direction in the p well PW1 below the semiconductor region pPS1. This makes it possible to suppress or prevent occurrence of punch-through at a position deeper than that of the semiconductor region pPS1.

In addition, the p type semiconductor region pPS2 is formed at a position deeper than that of the semiconductor region pPS1 so that it does not cause variations in the threshold voltage of the nMIS nQ3. This makes it possible to secure the operation stability of the nMIS nQ3. Structures and advantageous effects other than the above-mentioned ones are omitted, because they are similar to those of First Embodiment.

Next, one example of a method of manufacturing the semiconductor device according to Second Embodiment will be described referring to FIGS. 16 to 22. FIGS. 16 to 22 are fragmentary cross-sectional views of the substrate SS during manufacturing steps of the semiconductor device according to Second Embodiment.

First, as shown in FIG. 16, a pattern of a resist film RM5 is formed on the main surface of the substrate SS by using photolithography. This pattern of the resist film RM5 is formed so as to expose therefrom the formation region of the second punch-through stopper and cover the other region.

Then, with the resist film RM5 as a mask, for example, boron is introduced into the substrate SS by using an ion implantation process or the like to form a p type semiconductor region pPS2 for the second punch-through stopper in the substrate SS.

After removal of the resist film RM5, a gate insulating film GI1 is formed on the main surface of the substrate SS as shown in FIG. 17. Then, as shown in FIG. 18, similar to First Embodiment, a pattern of a hard mask film HM is formed on the main surface of the substrate SS.

Next, as shown in FIG. 19, similar to First Embodiment, a metal film M such as hafnium (Hf) film is deposited on the main surface of the substrate SS. The metal film M has a thickness of, for example, from about 0.5 to 1 nm. Instead of hafnium, another metal film such as titanium nitride (TiN) or aluminum (Al) film may be deposited.

After removal of the hard mask film HM by etching, a pattern of the metal film M is formed as shown in FIG. 20 so as to cover the semiconductor region pPS2 for second punch-through stopper.

Then, as shown in FIG. 21, after deposition of a gate electrode formation film GP on the main surface of the substrate SS similar to First Embodiment, it is patterned to form a gate electrode GP1 for nMIS as shown in FIG. 22. In the nMIS formation region, the gate insulating film and the gate electrode GP1 have, in a portion therebetween on the side of the source region, the metal film M. Steps after this patterning are similar to those described referring to FIGS. 10 to 14 so that a description on them is omitted.

### Third Embodiment

In First and Second Embodiments, patterning of the metal film M is conducted using a lift-off process, but the patterning process is not limited thereto. When the thickness of the metal film M is greater than that described in First Embodiment, the metal film M may be patterned using conventional photolithography. One example of it will be described referring to FIGS. 23 to 26. FIGS. 23 to 26 are fragmentary cross-sectional views of a substrate SS during manufacturing steps of a semiconductor device according to Third Embodiment.

First, as shown in FIG. 23, after formation of a gate insulating film GI1 on the main surface of the substrate SS, a metal film M is deposited on the main surface of the substrate SS by using a CVD process or the like without forming a hard mask film. The metal film M in this case is deposited with a thickness greater than that of First Embodiment.

Then, as shown in FIG. 24, a pattern of a resist film RM6 is formed on the metal film M by using photolithography. The pattern of this resist film RM6 is formed so as to cover the formation region of the pattern of the metal film M and expose the other region.

Then, as shown in FIG. 25, with the resist film RM6 as an etching mask, the metal film M exposed from the resist film RM6 is removed by etching such as wet etching, followed by removal of the resist film RM6 to form a pattern of the metal film M as shown in FIG. 26. Steps after this etching are similar to those described referring to FIGS. 8 to 14 so that a description on them is omitted.

In Third Embodiment having such a structure, a deposition step and a patterning step of a hard mask can be omitted, making it possible to simplify the manufacturing steps of a semiconductor device. In addition, a manufacturing time of the semiconductor device can be reduced. It is therefore possible to accelerate reduction in the manufacturing cost of the semiconductor device.

The invention made by the present inventors has been described specifically based on some embodiments. It is however borne in mind that the invention is not limited to them. Needless to say, it can be modified without departing from the gist of the invention.

For example, in First to Third Embodiments, the invention is applied to a high breakdown voltage nMIS. It may however be applied to a high breakdown voltage pMIS. Also in this case, it is recommended to provide a metal oxide film in a portion, on the side of a source region, between a gate insulating film and a gate electrode.

What is claimed is:

1. A semiconductor device comprising a first insulating gate field effect transistor having a metal oxide film in a portion, on the side of a source region, between a gate insulating film formed over a semiconductor substrate and a gate electrode formed over the gate insulating film.

2. The semiconductor device according to claim 1,
wherein a first semiconductor region having a conductivity type opposite to that of the source region is provided in the semiconductor substrate below the gate electrode so as to be adjacent to the source region, and
wherein the metal oxide film is provided above the first semiconductor region.

3. The semiconductor device according to claim 2,
wherein the metal oxide film is provided so as to cover the entirety of the first semiconductor region below the gate electrode.

4. The semiconductor device according to claim 2,
wherein a second conductor region having the same conductivity type as that of the first semiconductor region is provided below the first semiconductor region.

5. The semiconductor device according to claim 1,
wherein a second insulating gate field effect transistor having a drive voltage lower than that of the first insulating gate field effect transistor is provided over the semiconductor substrate.

6. The semiconductor device according to claim 5,
wherein the metal oxide film is provided in the entire region between a gate insulating film and a gate electrode of the second insulating gate field effect transistor.

7. The semiconductor device according to claim 1,
wherein the metal oxide film is a hafnium oxide, titanium oxynitride, or aluminum oxide film.

8. The semiconductor device according to claim 1,
wherein the gate insulating film is a silicon oxide or silicon oxynitride film.

9. The semiconductor device according to claim 1,
wherein the metal oxide film is not formed on the side of a drain region of the first insulating gate field effect transistor.

10. A method comprising the steps of:
manufacturing a semiconductor device in forming a first insulating gate field effect transistor over a semiconductor substrate,
forming a metal oxide film in a portion, on the side of a source region, between a gate insulating film and a gate electrode of the first insulating gate field effect transistor.

11. The method comprising the steps of:
manufacturing a semiconductor device according to claim 10,
forming a first semiconductor region having a conductivity type opposite to that of the source region so as to be adjacent to the source region in the semiconductor substrate below the gate electrode, and
forming the metal oxide film above the first semiconductor region in the step of forming a metal oxide film.

12. The method comprising the step of:
manufacturing a semiconductor device according to claim 11,
wherein the metal oxide film is formed so as to cover the entirety of the first semiconductor region below the gate electrode in the step of forming a metal oxide film.

13. The method comprising the steps of:
manufacturing a semiconductor device according to claim 10,
forming a second semiconductor region having the same conductivity type as that of the first semiconductor region below the first semiconductor region.

14. The method comprising the steps of:
manufacturing a semiconductor device according to claim 10,
forming a pattern of a metal film for the formation of the metal oxide film by using a lift-off process.

15. The method comprising the steps of:
manufacturing a semiconductor device according to claim 10,
forming a pattern of a metal film for the formation of the metal oxide film by using an etching process.

16. The method comprising the steps of:
manufacturing a semiconductor device according to claim 10,
forming a second insulating gate field effect transistor having a drive voltage lower than that of the first insulating gate field effect transistor over the semiconductor substrate.

17. The method comprising the steps of:
manufacturing a semiconductor device according to claim 16,
forming the metal oxide film in the entire region between a gate insulating film and a gate electrode of the second insulating gate field effect transistor.

18. The method comprising the step of:
manufacturing a semiconductor device according to claim 10,
wherein the metal oxide film is a hafnium oxide, titanium oxynitride, or aluminum oxide film.

19. The method comprising the step of:
manufacturing a semiconductor device according to claim 10,
wherein the gate insulating film is a silicon oxide or silicon oxynitride film.

20. The method comprising the step of:
manufacturing a semiconductor device according to claim 10,
wherein the metal oxide film is not formed on the side of a drain region of the first insulating gate field effect transistor.
